(19) United States
(12) Patent Application Publication
(10) Pub. No.: US 2026/0190954 A1
(43) Pub. Date: Jul. 2, 2026

(54) BONDING METHOD, WAFER STACKING STRUCTURE, AND CHIP STRUCTURE

(71) Applicant: WUHAN XINXIN SEMICONDUCTOR MANUFACTURING CO., LTD., WUHAN (CN)

(72) Inventors: Hu YANG, WUHAN (CN); Yu ZHOU, WUHAN (CN); Sheng HU, WUHAN (CN); Guoliang YE, WUHAN (CN)

(21) Appl. No.: 19/547,345

(22) Filed: Feb. 23, 2026

Related U.S. Application Data
(63) Continuation of application No. PCT/CN2023/125732, filed on Oct. 20, 2023.

(30) Foreign Application Priority Data
Sep. 8, 2023 (CN) 202311168510.5

(51) Int. Cl. H10P 74/20; H10P 58/00; H10W 90/20; H10W 90/26

(52) U.S. Cl. CPC H10P 74/207; H10P 58/00; H10W 90/26; H10W 90/284

(57) ABSTRACT

A bonding method, a wafer stacking structure, and a chip structure are provided. The bonding method includes: providing at least one first wafer stacking structure, and testing each chip region of the first wafer stacking structure, the first wafer stacking structure includes at least two first wafers bonded together; dicing the first wafer stacking structure to form chips, each of the chips corresponding to a corresponding one chip region; and bonding a chip with good functions, which corresponds to a corresponding chip region with good functions determined in the operation of testing each chip region of the first wafer stacking structure, to a second wafer.

### CROSS REFERENCE TO RELATED APPLICATIONS

This present disclosure is a continuation of International Patent Application No. PCT/CN2023/125732, filed Oct. 20, 2023, which claims priority to the Chinese Patent Application No. 202311168510.5, filed Sep. 8, 2023, both of which are herein incorporated by reference in their entireties.

### TECHNICAL FIELD

The present disclosure relates to the field of semiconductor device technologies, and in particular to a bonding method, a wafer stacking structure, and a chip structure.

### BACKGROUND

With the continuous development of semiconductor technologies, a three-dimensional integrated circuit (3D-IC) technology has been widely applied, and chip structures are developing in three dimensions. a chip-to-wafer (C2W) stacking structure can integrate different functions, thereby improving performance, enhancing functionality, and reducing size.

In the current C2W stacking structure, multiple wafers are sequentially bonded together to form a multi-layer wafer bonding structure. The wafer stacking structure is diced to obtain corresponding chip structures. However, a wafer is difficult to maintain a 100% yield rate, during the stacking process of the multi wafers, as the number of wafer stacking layers increases, the yield rate of the bonded wafer stacking structure gradually decreases, resulting in increasing losses.

### SUMMARY

A first aspect of the present disclosure provides a bonding method. The bonding method includes: providing at least one first wafer stacking structure, and testing each chip region of the first wafer stacking structure, the first wafer stacking structure includes at least two first wafers bonded together; dicing the first wafer stacking structure to form chips, each of the chips corresponding to a corresponding one chip region; and bonding a chip with good functions, which corresponds to a corresponding chip region with good functions determined in the operation of testing each chip region of the first wafer stacking structure, to a second wafer.

A second aspect of the present disclosure provides wafer stacking structure. The wafer stacking structure includes a functional wafer and at least one first chip bonded to the functional wafer. The first chip includes at least two dies bonded together, and a test lead-out metal piece is formed on a die in an outer side of the first chip.

A third aspect of the present disclosure provides a chip structure. The chip structure includes at least one first chip. The first chip includes at least two dies bonded together, and a test lead-out metal piece is formed on a die in an outer side of the first chip.

### BRIEF DESCRIPTION OF THE DRAWINGS

In order to more clearly illustrate embodiments and examples of the present disclosure, one or more drawings may be referred. The additional details or examples used to describe the drawings should not be considered as limiting the scope of any of the present disclosure, the embodiments and/or examples, and the best manner of the present disclosure as currently understood.

FIG. 1 is a schematic structural diagram of a bonding structure of two wafers in the related art.

FIG. 2 is a schematic structural diagram of a bonding structure of two wafers in the related art, and the one wafer includes through-silicon vias and bonding metal patterns.

FIG. 3 is a schematic structural diagram of a bonding structure of three wafers in the related art.

FIG. 4 is a schematic structural diagram of a wafer stacking structure with multiple wafers bonded together in the related art.

FIG. 5 is a flowchart of a bonding method according some embodiments of the present disclosure.

FIG. 6 is a sub-flowchart of the operation S11 in FIG. 5 according some embodiments of the present disclosure.

FIG. 7 is a schematic structural diagram of a first wafer stacking structure according some embodiments of the present disclosure.

FIG. 8 is a schematic structural diagram of a wafer structure after processing by the operation S112 in FIG. 6.

FIG. 9 is a sub-flowchart of the operation S112 in FIG. 6 according some embodiments of the present disclosure.

FIG. 10 is a schematic structural diagram of a wafer structure after processing by the operations S114 and S115 in FIG. 6.

FIG. 11 is a sub-flowchart of the operation S12 in FIG. 5 according some embodiments of the present disclosure.

FIG. 12 is a schematic structural diagram of a wafer structure after processing by the operation S121 in FIG. 11.

FIG. 13 is a schematic structural diagram of a wafer structure after processing by the operation S122 in FIG. 11.

FIG. 14 is a schematic structural diagram of a wafer structure after processing by the operation S123 in FIG. 11.

FIG. 15 is a schematic structural diagram of a wafer structure after processing by the operation S124 of transferring chips to a wafer frame through a carrier wafer in FIG. 11.

FIG. 16 is a schematic structural diagram of a wafer structure after processing by the operation S124 of debonding and removing the carrier wafer in FIG. 11.

FIG. 17 is a schematic structural diagram of a wafer structure that is bonded to one chip determined to have good functions by testing in the operation S13 in FIG. 5.

FIG. 18 is a schematic structural diagram of a wafer structure that is bonded to multiple chips determined to have good functions by testing in the operation S13 in FIG. 5.

FIG. 19 is a schematic structural diagram of a wafer stacking structure according some embodiments of the present disclosure.

FIG. 20 is a schematic structural diagram of a chip structure according some embodiments of the present disclosure.

### DETAILED DESCRIPTIONS

The technical solutions in embodiments of the present disclosure are clearly and completely described in conjunction with the drawings in the embodiments of the present disclosure. Apparently, the described embodiments are only some embodiments of the present disclosure, and not all embodiments. All other embodiments obtained by those skilled in the art based on the embodiments in the present disclosure without any creative work are all within the scope of the present disclosure.

Terms “first”, “second” and “third” in the present disclosure are used for descriptive purposes only and shall not be interpreted as indicating or implying relative importance or implicitly specifying the number of technical features indicated. Therefore, a feature defined by “first”, “second”, and “third” may include at least one such feature either explicitly or implicitly. In the description of the present disclosure, terms “plurality” and “multiple” means at least two, such as two, three, and so on, unless otherwise expressly and specifically limited. All directional indications (such as up, down, left, right, front, rear, ...) in the embodiments of the present disclosure are used only to explain relative positional relationships and relative movements between components disposed in a particular attitude (the attitude as shown in the drawings). If the particular attitude changes, the directional indication changes accordingly. Furthermore, terms “include”, “have”, and any variations thereof, are intended to cover non-exclusive inclusion. For example, a process, a method, a system, a product or an apparatus including a series of operations or units is not limited to the listed operations or units, but optionally further includes operations or units that are not listed, or optionally includes other operations or units that are inherently included in the process, the method, the product or the apparatus.

“Embodiments” herein implies that particular features, structures, or characteristics described in an embodiment may be included in at least one embodiment of the present disclosure. Presence of the term at various sections in the specification does not necessarily refer to one same embodiment, nor a separate or alternative embodiment that is mutually exclusive of other embodiments. It is understood by those skilled in the art, both explicitly and implicitly, that the embodiments described herein may be combined with other embodiments.

In embodiments of the present disclosure, a “front surface” of a wafer refers to a surface where electronic components are arranged, and a “back surface “refers to a surface opposite to the “front surface”. The wafer bonding mentioned in embodiments of the present disclosure is not limited to bonding between a front surface of a wafer and a back surface of another wafer, but may include bonding between a front surface of a wafer and a front surface of another wafer or bonding between a back surface of a wafer and a back surface of another wafer.

The present disclosure is described in detail in conjunction with the drawings and some embodiments.

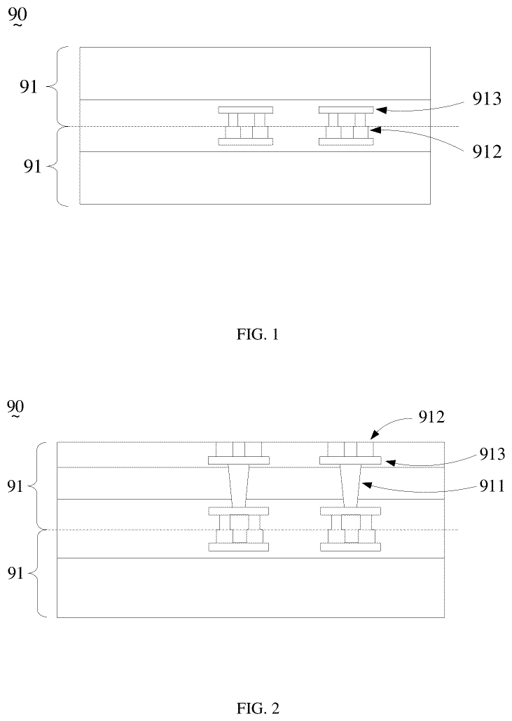

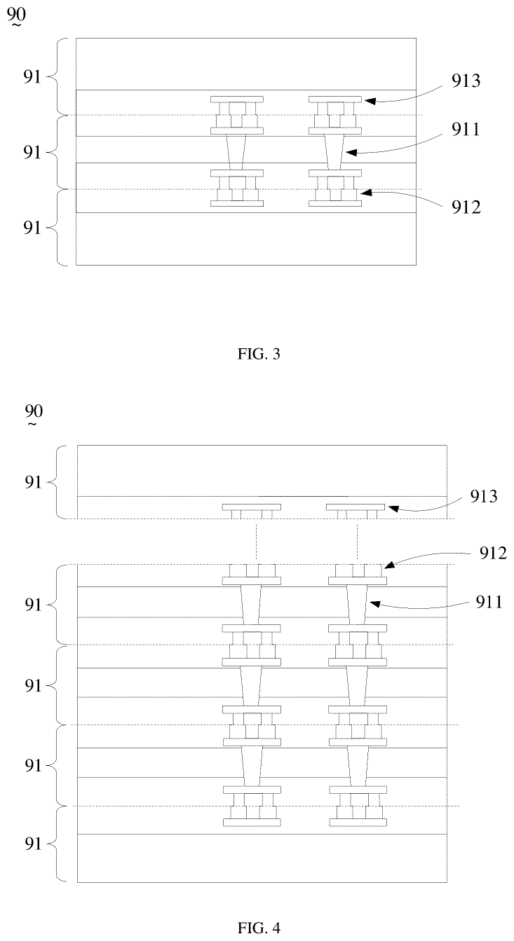

FIG. 1 is a schematic structural diagram of a bonding structure of two wafers in the related art; FIG. 2 is a schematic structural diagram of a bonding structure of two wafers in the related art, and the one wafer includes through-silicon vias and bonding metal patterns; FIG. 3 is a schematic structural diagram of a bonding structure of three wafers in the related art; and FIG. 4 is a schematic structural diagram of a wafer stacking structure with multiple wafers bonded together in the related art.

As shown in FIGS. 1-4, in the related art, in a wafer stacking structure 90, multiple wafers 91 are sequentially bonded together to form a multi-layer wafer bonding structure. First, two wafers 91 are bonded together by bonding a front surface of the one wafer 91 to a front surface of the another wafer 91 to form a 2-layer wafer stacking structure. Before bonded to a third wafer 91, a back surface of one of the two wafers is thinned and a through-silicon via (TSV) 911, a metal layer 913, and a bonding metal pattern 912 are formed, the metal layer 913 on the back surface and the metal layer 913 on the front surface of the wafer 91 are connected to each other through the TSV 911. Then, the third wafer 91 is bonded to form a 3-layer wafer stacking structure. The above processes are repeated until a desired multi-layer wafer stacking structure 90 is formed. However, a wafer is difficult to maintain a 100% yield rate, during the wafer stacking process, as the number of wafer stacking layers increases, the yield rate of the bonded wafer stacking structure gradually decreases, resulting in increasing losses. For example, if the yield rate of one wafer before bonded is 96% (assuming the yield rate of bonding between two wafers is 100%), then after 4 stacking processes, i.e., forming a 5-layer wafer stacking structure, the yield rate decreases to 82%. After 8 stacking processes, i.e., forming a 9-layer wafer stacking structure, the yield rate decreases to 69%, that is, the 9-layer wafer stacking structure incurs the cost of the process itself and an additional 31% yield loss.

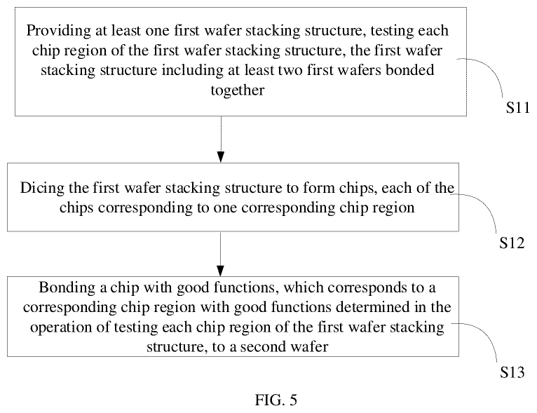

To solve the above problems, a first aspect of the present disclosure provides a bonding method. As shown in FIG. 5, FIG. 5 is a flowchart of a bonding method according some embodiments of the present disclosure. The method specifically includes following operations.

An operation S11 may include: providing at least one first wafer stacking structure, testing each chip region of the first wafer stacking structure, the first wafer stacking structure including at least two first wafers bonded together.

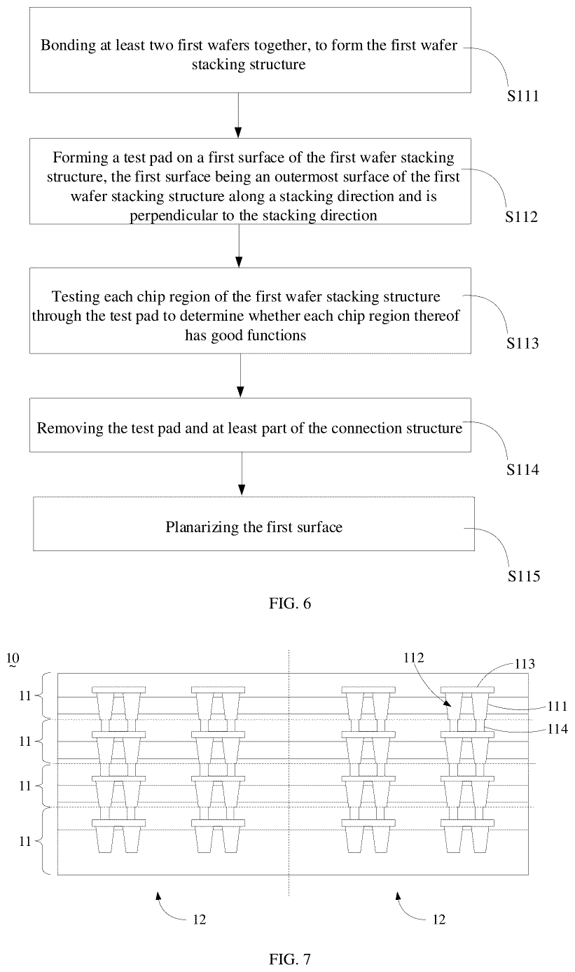

In some embodiments, as shown in FIG. 6, FIG. 6 is a sub-flowchart of the operation S11 in FIG. 5 according some embodiments of the present disclosure. The operation S11 may following operations.

An Operation S111 may includes: sequentially bonding at least two first wafers together, to form the first wafer stacking structure.

As shown in FIG. 7, FIG. 7 is a schematic structural diagram of a first wafer stacking structure according some embodiments of the present disclosure. In this embodiment, a first wafer stacking structure 10 is formed by bonding 4 first wafers 11 together. The first wafer stacking structure 10 includes at least one chip region 12. Each first wafer 11 includes at least one TSV 111 and a metal layer 113. The TSV 111 is filled with a conductive material to form a metal pillar 112. The conductive material may be copper, tungsten, or other metal materials. The metal layers 113 of adjacent first wafers 11 are electrically connected to each other through the TSV 111 and a corresponding bonding metal pattern 114 in one of the adjacent first wafers 11. In other embodiments, depending on different requirements or functions, the first wafer stacking structure 10 may be formed by stacking at least 2 first wafers 11, such as 3, 5, 6, or other numbers of first wafers 11. In some embodiments, the TSV 111 is manufactured by a via-middle and a backside via review (BVR), i.e., the TSV 111 is manufactured after a front end of line (FEOL, such as manufacture of transistors) and a middle of line (MOL, such as metal contact) but before a back end of line (BEOL, such as manufacture of metal layers). In other embodiments, to achieve different functions, the TSV 111 may be manufactured by other processes, such as a via-first or a via-last. In some embodiments, the metal layer 113 and bonding metal pattern 114 may be formed by photolithography, etching, and other processes.

An operation S112 may includes: forming a test pad on a first surface of the first wafer stacking structure, the first surface being an outermost surface of the first wafer stacking structure along a stacking direction and is perpendicular to the stacking direction.

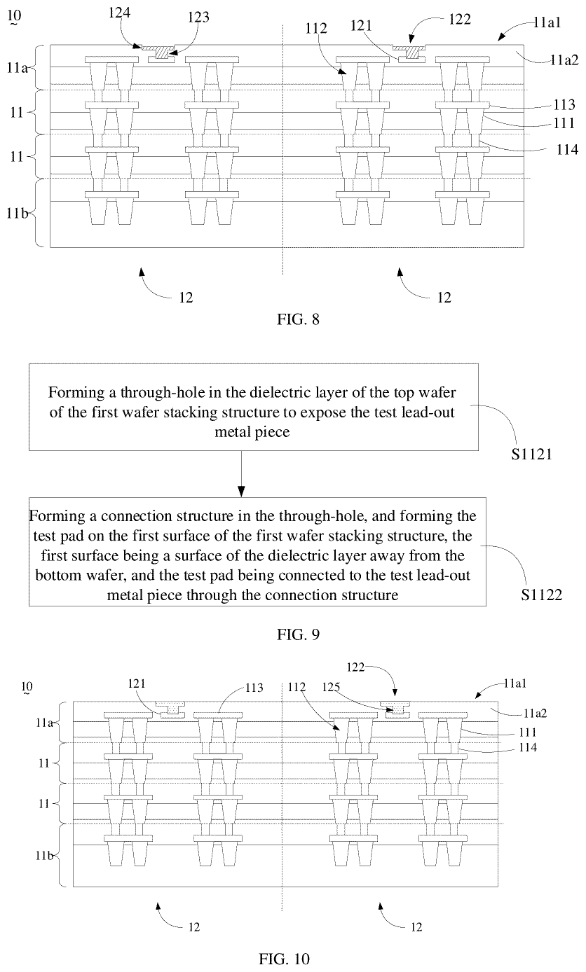

In some embodiments, as shown in FIG. 8, FIG. 8 is a schematic structural diagram of a wafer structure after processing by the operation S112 in FIG. 6. In this embodiment, all the first wafers 11 of the first wafer stacking structure 10 being bonded together by bonding a front surface of the one wafer 11 to a back surface of the other wafer 11 are taken as an example. In this embodiment, the first wafer stacking structure 10 includes a top wafer 11a and bottom wafer 11b, the top wafer 11a is located at an outermost side of the first wafer stacking structure 10 and is perpendicular to the stacking direction, and the bottom wafer 11b is located at the another outermost side of the first wafer stacking structure 10 and is arranged opposite to the top wafer 11a. A front surface of the top wafer 11a, i.e., a surface of the outermost side of the first wafer stacking structure 10, is a first surface 11a1. The top wafer 11a has a reserved test lead-out metal piece 121. In some embodiments, the test lead-out metal piece 121 is formed simultaneously with the metal layer 113 in a dielectric layer 11a2 of the top wafer 11a, and the test lead-out metal piece 121 is electrically connected to the simultaneously formed metal layer 113.

In some embodiments, as shown in FIG. 9, FIG. 9 is a sub-flowchart of the operation S112 in FIG. 6 according some embodiments of the present disclosure. The operation S112 may include following operations.

An operation S1121 may includes: forming a through-hole in the dielectric layer of the top wafer of the first wafer stacking structure to expose the test lead-out metal piece.

Continuing to refer to FIG. 8, the top wafer 11a includes a dielectric layer 11a2 arranged on the side of the top wafer 11a away from the bottom wafer 11b. The test lead-out metal piece 121 is embedded in the dielectric layer 11a 2. A through-holes 122 is formed in the dielectric layer 11a 2, and the through-hole 122 is located on the side of the test lead-out metal piece 121 away from the bottom wafer 11b to expose the test lead-out metal piece 121.

An operation S1122 may includes: forming a connection structure in the through-hole, and forming the test pad on the first surface of the first wafer stacking structure, the first surface being a surface of the dielectric layer away from the bottom wafer, and the test pad being connected to the test lead-out metal piece through the connection structure.

Continuing to refer to FIG. 8, the through-hole 122 is filled with a conductive material to form a connection structure 123, and test pad 124 is formed on the first surface 11a1, enabling electrical connection between the test lead-out metal piece 121 and the test pad 124. Since aluminum has an anti-oxidation property compared to other metals such as copper, in some embodiments, the conductive material filled in the through-holes 122 is aluminum.

An operation S113 may includes: testing each chip region of the first wafer stacking structure through the test pad to determine whether each chip region thereof has good functions.

In some embodiments, the test performed on each chip region 12 includes but is not limited to: wafer an acceptance test (WAT) and a chip probing (CP). The WAT is configured to test a particular test key to monitor whether each process step is normal and stable through electrical parameters. The CP is configured to test a wafer and includes testing basic device parameters such as a threshold voltage (vt) and a specific on-resistance (Rdson), etc. Based on these tests, chip regions 12 with good functions may be identified and marked. In some embodiments, the chip regions 12 with good functions are chip regions that may achieve corresponding electrical functions.

In this embodiment, as shown in FIG. 6, after the operation S113, the following two operations may be included.

An operation S114 may includes: removing the test pad and at least part of the connection structure.

An operation S115 may includes: planarizing the first surface.

In some embodiments, as shown in FIG. 10, FIG. 10 is a schematic structural diagram of a wafer structure after processing by the operations S114 and S115 in FIG. 6. After testing and screening the chip regions with good functions, the test pad 124 and connection structure 123 are required to be removed, i.e., the electrical connection between the test lead-out metal piece 121 and the external of a corresponding chip region 12 is required to be disconnected. To reduce hindering subsequent chip stacking, the through-hole 122 is required to be filled with a non-conductive material to form an insulating layer 125, and the first surface 11a1 is required to be planarized. For the removal of the test pad 124 and connection structure 123, during the removal process, the test pad 124 and connection structure 123 may be completely removed, or only a part of the test pad 124 and connection structure 123 away from the bottom wafer 11b may be removed, or a part of the first dielectric layer 11a2 around the test pad 124 and connection structure 123 may also be removed while the test pad 124 and connection structure 123 are removed, as long as the electrical connection between the test lead-out metal piece 121 and the external of the corresponding chip region 12 is disconnected and subsequent chip stacking is not hindered. In some embodiments, wet etching is adopted to etch the conductive material, i.e., aluminum, filled in the through-holes 122, thereby removing the test pad 124 and connection structure 123. After the etching process, in some embodiments, oxide deposition process is adopted to fill the through-hole 122, the oxide deposition process may include filling silicon dioxide. Then chemical mechanical polishing (CMP) is adopted to planarize the first surface 11a1. In other embodiments, the conductive material may be removed by other methods, such as chemical etching, reactive ion etching, or other dry etching methods, etc.

An operation S12 may include: dicing the first wafer stacking structure to form chips, each of the chips corresponding to one corresponding chip region.

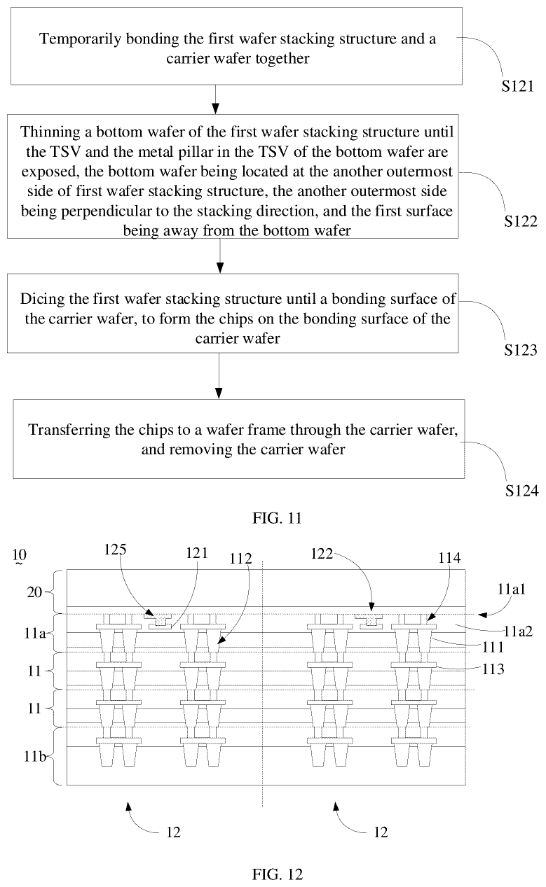

In some embodiments, as shown in FIG. 11, FIG. 11 is a sub-flowchart of the operation S12 in FIG. 5 according some embodiments of the present disclosure. The operation S12 may include following operations.

An operation S121 may include: temporarily bonding the first wafer stacking structure and a carrier wafer together.

In some embodiments, as shown in FIG. 12, FIG. 12 is a schematic structural diagram of a wafer structure after processing by the operation S121 in FIG. 11. Before dicing the first wafer stacking structure 10, a carrier wafer 20 is required to be bonded to the first wafer stacking structure 10. In this embodiment, the first surface 11a1 is bonded to the carrier wafer 20, and the first wafer stacking structure 10 and the carrier wafer 20 are bonded together in a temporary manner. To facilitate subsequent chip stacking, before bonding, a bonding metal pattern 114 may be formed in the dielectric layer 11a2, and the bonding metal pattern 114 is connected to the metal layer 113 of the top wafer 11a. In some embodiments, the bonding metal pattern 114 is formed by etching, deposition, and other processes.

An operation S122 may includes: thinning a bottom wafer of the first wafer stacking structure until the TSV and the metal pillar in the TSV of the bottom wafer are exposed, the bottom wafer being located at the another outermost side of first wafer stacking structure, the another outermost side being perpendicular to the stacking direction, and the first surface being away from the bottom wafer.

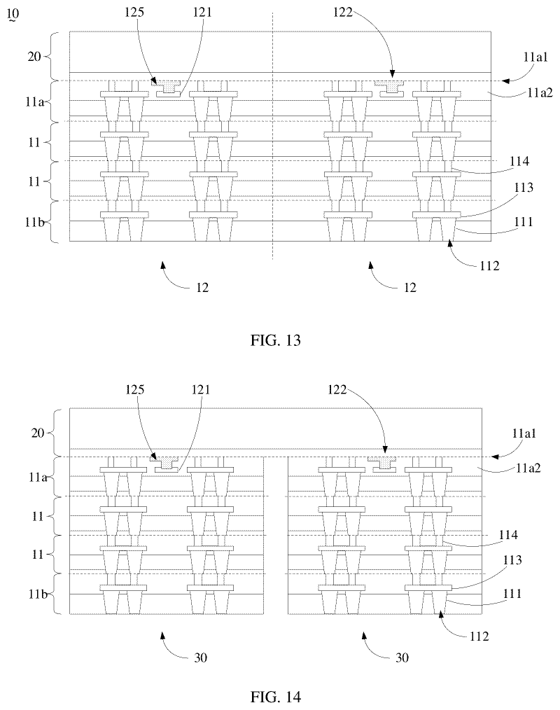

In some embodiments, as shown in FIG. 13, FIG. 13 is a schematic structural diagram of a wafer structure after processing by the operation S122 in FIG. 11. To facilitate subsequent chip stacking, a surface of the bottom wafer 11b away from the top wafer 11a, i.e., the back surface of the bottom wafer 11b, is required to be thinned, and the TSV 111 and the metal pillar 112 in the TSV 111 of the bottom wafer 11b are required to be exposed. In some embodiments, the BVR process is still adopted to thin the bottom wafer 11b.

In this embodiment, the carrier wafer 20 is temporarily bonded first, and then the bottom wafer 11b of the first wafer stacking structure 10 is thinned. In other embodiments, the bottom wafer 11b of the first wafer stacking structure 10 may be thinned first, and then the carrier wafer 20 may be temporarily bonded, as long as subsequent chip stacking is not hindered.

An operation S123 may include: dicing the first wafer stacking structure until a bonding surface of the carrier wafer, to form the chips on the bonding surface of the carrier wafer.

In some embodiments, as shown in FIGS. 13-14, FIG. 14 is a schematic structural diagram of a wafer structure after processing by the operation S123 in FIG. 11. In some embodiments, each chip region 12 is first defined through scribe line photolithography, then the first wafer stacking structure 10 is diced through etching to separate each chip region 12 and form chips 30. Since the temporarily bonded carrier wafer 20 is configured to carry the chip 30 and does not participate in subsequent chip stacking, to facilitate the removal of the carrier wafer 20, in some embodiments, the etching of the first wafer stacking structure 10 stops at the bonding surface of the carrier wafer 20. In this way, multiple chips 30 bonded to the carrier wafer 20 are obtained.

An operation S124 may include: transferring the chips to a wafer frame through the carrier wafer, and removing the carrier wafer.

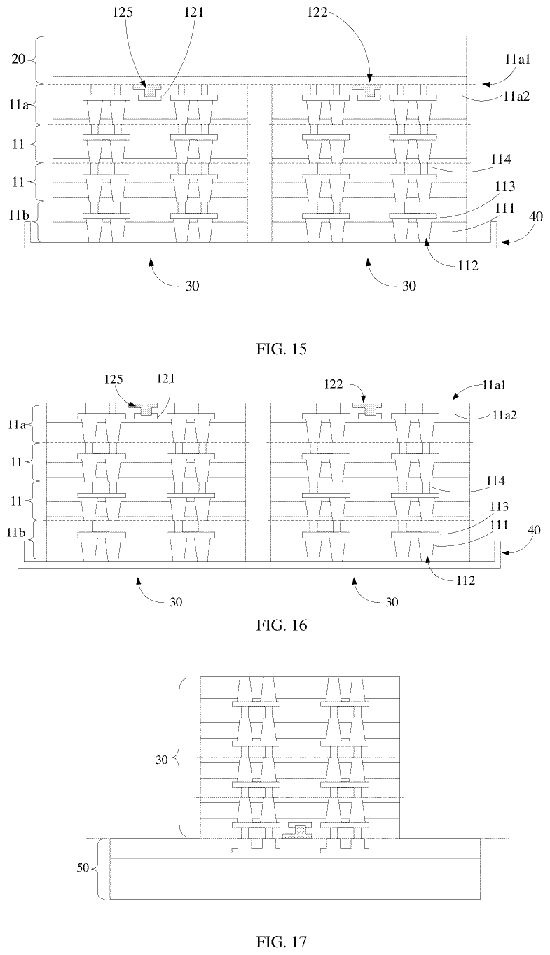

In some embodiments, as shown in FIGS. 15-16, FIG. 15 is a schematic structural diagram of a wafer structure after processing by the operation S124 of transferring chips to a wafer frame through a carrier wafer in FIG. 11, and FIG. 16 is a schematic structural diagram of a wafer structure after processing by the operation S124 of debonding and removing the carrier wafer in FIG. 11. In this embodiment, to facilitate the removal of the carrier wafer 20 and support and fixing the chips 30 after the removal of the carrier wafer 20, the chips 30 are required to be transferred to a wafer frame 40 before removing the carrier wafer 20, surfaces of the chips 30 away from the carrier wafer 20 contact the wafer frame 40. In this embodiment, the carrier wafer 20 is removed through debonding. In other embodiments, the carrier wafer may be removed through etching, CMP, or other methods. In some embodiments, the wafer frame 40 is a blue film or UV film (such as an ultraviolet irradiation tape).

An operation S13 may include: bonding a chip with good functions, which corresponds to a corresponding chip region with good functions determined in the operation of testing each chip region of the first wafer stacking structure, to a second wafer.

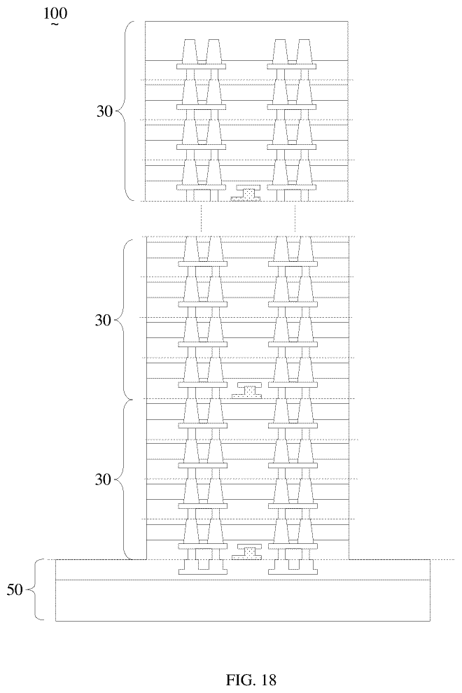

In some embodiments, as shown in FIGS. 17-18, FIG. 17 is a schematic structural diagram of a wafer structure that is bonded to one chip determined to have good functions by testing in the operation S13 in FIG. 5, and FIG. 18 is a schematic structural diagram of a wafer structure that is bonded to multiple chips determined to have good functions by testing in the operation S13 in FIG. 5. After the above operations, in this embodiment, a chip-to-wafer bonding technology is adopted to sequentially bond multiple chips 30 with good functions, which correspond to corresponding chip regions with good functions determined in the operation of testing each chip region of the first wafer stacking structure, to a second wafer 50, and a multi-layer wafer stacking structure 100 is formed. In some embodiments, the second wafer 50 is a functional wafer, such as a logic wafer.

The bonding method provided in some embodiments includes: providing the first wafer stacking structure 10 with at least a two layer, testing each chip region 12, identifying and marking chip regions 12 with good functions, dicing the first wafer stacking structure 10 to obtain multiple chips 30, each of the multiple chips 30 corresponding to one corresponding chip region 12, so as to obtain multiple chips 30 with good functions in a selectable manner. Finally, the chip-to-wafer bonding technology is adopted to sequentially bond the multiple chips 30 with good functions, which correspond to corresponding chip regions with good functions determined in the operation of testing each chip region 12, to the second wafer 50. In this way, the multi-layer wafer stacking structure 100 may be obtained, and each chip 30 to be bonded and stacked has good functions, thereby maintaining a high yield rate of the wafer stacking structure 100.

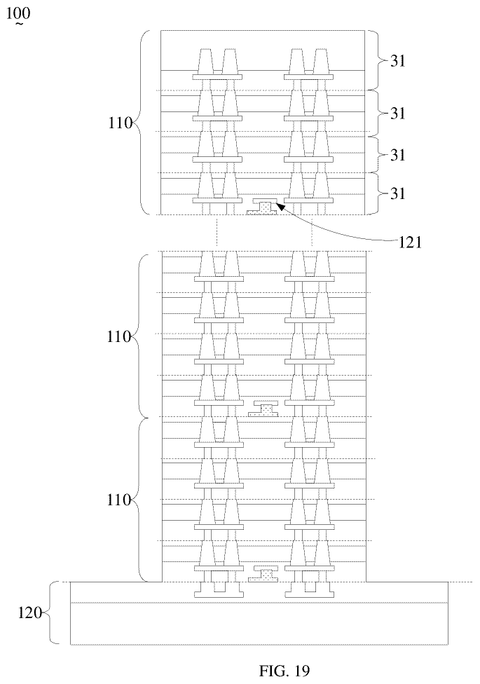

Further, to solve the above problems, a second aspect of the present disclosure provides a wafer stacking structure. In some embodiments, as shown in FIG. 19, FIG. 19 is a schematic structural diagram of a wafer stacking structure according some embodiments of the present disclosure. A wafer stacking structure 100 may include at least one first chip 110 and a functional wafer 120. In this embodiment, multiple first chips 110 are sequentially bonded to the functional wafer 120 to form a multi-layer stacking structure. The first chips 110 are obtained by dicing the first wafer stacking structure 10 mentioned above, and the first chips 110 correspond to the chip regions 12 with good functions, i.e., the first chips 110 are chips with good functions of the multiple chips 30 obtained by dicing the first wafer stacking structure 10 mentioned above. That is, the first wafer stacking structure 10 may include at least two first wafers 11 bonded together, and the multiple chips 30 may be obtained by dicing the first wafer stacking structure 10, from the multiple chips 30 obtained through dicing, chips 30 with good functions are selected as the first chips 110 for the subsequent operations described in the above embodiments of the present disclosure. Additionally, those skilled in the art can understand that when the first wafer stacking structure 10 is diced, each first wafer 11 in the first wafer stacking structure 10 is also diced into multiple dies 31, so that the chips 30 and first chips 110 obtained through dicing are formed by stacking at least two dies 31 corresponding to the first wafer 11 in the first wafer stacking structure 10.

In some embodiments, a test lead-out metal piece 121 that has been tested is formed on one die 31 in the outer side of each first chip 110. In some embodiments, the die 31 in the outer side of each first chip 110 is configured to be bonded to the functional wafer 120 or another adjacent first chip 110. In some embodiments, the functional wafer 120 is a logic wafer. In other embodiments, the functional wafer may be a wafer that achieves other functions.

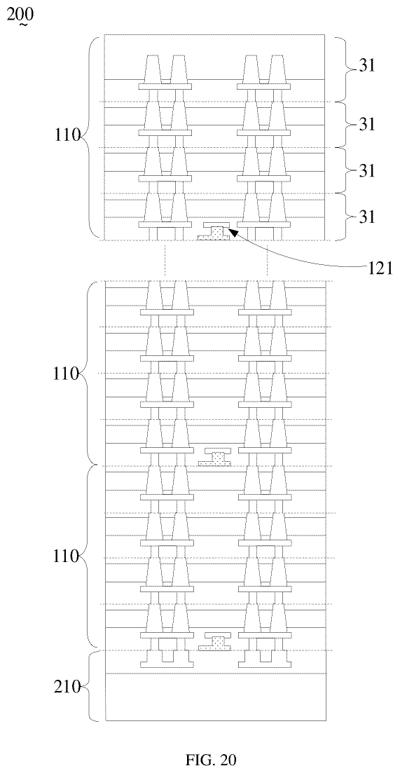

Further, to solve the above problems, a third aspect of the present disclosure provides a chip structure. In some embodiments, as shown in FIG. 20, FIG. 20 is a schematic structural diagram of a chip structure according some embodiments of the present disclosure. A chip structure 200 may include at least one first chip 110. Similarly, the first chip 110 is obtained by dicing the first wafer stacking structure 10 mentioned above and corresponds to the chip regions 12 with good functions, i.e., the first chip 110 is a chip with good functions. Similarly, the first chip 110 is formed by stacking at least two dies 31.

In some embodiments, the test lead-out metal piece 121 that has been tested is formed on a die 31 in an outer side of the first chip 110 of the chip structure 200. In some embodiments, the chip structure 200 may include a functional die 210, and the functional die 210 is bonded to the die 31 in the outer side of the first chip 110. When the chip structure 200 includes multiple first chips 110 bonded together, the die 31 in the outer side of each first chip 110 is configured to be bonded to the functional die 210 or another adjacent first chip 110. In some embodiments, the functional die 210 is a logic die. In other embodiments, the functional die may be a die that achieves other functions.

The above shows only embodiments of the present disclosure, but does not limit the scope of the present disclosure. Any equivalent structure or equivalent process transformations made based on the contents of the specification and the accompanying drawings of the present disclosure, applied directly or indirectly in other related technical fields, shall be similarly included in the scope of the present disclosure.

1. A bonding method, comprising:
providing at least one first wafer stacking structure, and testing each chip region of the first wafer stacking structure, wherein the first wafer stacking structure comprises at least two first wafers bonded together;
dicing the first wafer stacking structure to form chips, each of the chips corresponding to a corresponding one chip region; and
bonding a chip with good functions, which corresponds to a corresponding chip region with good functions determined in the operation of testing each chip region of the first wafer stacking structure, to a second wafer.

2. The bonding method according to claim 1, wherein
the providing at least one first wafer stacking structure, and testing each chip region of the first wafer stacking structure, comprises:
sequentially bonding the at least two first wafers together, to form the first wafer stacking structure;
forming a test pad on a first surface of the first wafer stacking structure, wherein the first surface is an outermost surface of the first wafer stacking structure along a stacking direction and is perpendicular to the stacking direction; and
testing each chip region of the first wafer stacking structure through the test pad to determine whether each chip region thereof has good functions.

3. The bonding method according to claim 2, wherein
the first wafer stacking structure comprises a top wafer and a bottom wafer, the top wafer is located at an outermost side of the first wafer stacking structure and perpendicular to the stacking direction, the bottom wafer is located at another outermost side of the first wafer stacking structure and arranged opposite to the top wafer, the top wafer has a reserved test lead-out metal piece, and the first surface is away from the bottom wafer;
the forming a test pad on a first surface of the first wafer stacking structure, comprises:
forming a through-hole in a dielectric layer of the top wafer of the first wafer stacking structure to expose the test lead-out metal piece; and
forming a connection structure in the through-hole, and forming the test pad on the first surface of the first wafer stacking structure, wherein the first surface is a surface of the dielectric layer away from the bottom wafer, and the test pad is connected to the test lead-out metal piece through the connection structure.

4. The bonding method according to claim 3, wherein the connection structure has a conductivity and an anti-oxidation property.

5. The bonding method according to claim 3, wherein the top wafer comprises a metal layer, and the metal layer of the top wafer is electrically connected to the test lead-out metal piece.

6. The bonding method according to claim 5, wherein the first wafers comprise a metal layer, the bottom wafer comprises a metal layer;
the metal layer of the top wafer is electrically connected to the metal layer of the first wafers, and the metal layer of the bottom wafer is electrically connected to the metal layer of the first wafers.

7. The bonding method according to claim 2, wherein the testing each chip region of the first wafer stacking structure through the test pad to determine whether each chip region thereof has good functions, comprises:
performing a wafer an acceptance test (WAT) and a chip probing (CP) to identify and mark the corresponding chip region with good functions.

8. The bonding method according to claim 3, wherein
after the testing each chip region of the first wafer stacking structure through the test pad, the bonding method further comprises:
removing the test pad and at least a part of the connection structure; and
planarizing the first surface.

9. The bonding method according to claim 8, wherein the removing the test pad and at least a part of the connection structure, comprises:
removing the test pad and at least a part of the connection structure through wet etching, chemical etching, or reactive ion etching.

10. The bonding method according to claim 8, wherein the planarizing the first surface, comprises:
planarizing the first surface through chemical mechanical polishing.

11. The bonding method according to claim 8, after the removing the test pad and at least a part of the connection structure, the bonding method further comprising:
filling the through-hole through oxide deposition process.

12. The bonding method according to claim 1, wherein
the dicing the first wafer stacking structure to form chips, each of the chips corresponding to a corresponding one chip region, comprises:
temporarily bonding the first wafer stacking structure and a carrier wafer together;
dicing the first wafer stacking structure until a bonding surface of the carrier wafer, to form the chips on the bonding surface of the carrier wafer; and
transferring the chips to a wafer frame through the carrier wafer, and removing the carrier wafer.

13. The bonding method according to claim 12, wherein the dicing the first wafer stacking structure until a bonding surface of the carrier wafer, to form the chips on the bonding surface of the carrier wafer, comprises:
defining each chip region through scribe line photolithography, and then dicing the first wafer stacking structure until a bonding surface of the carrier wafer through etching, to separate each chip region and form the chips on the bonding surface of the carrier wafer.

14. The bonding method according to claim 12, wherein the removing the carrier wafer, comprises:
removing the carrier wafer through debonding, etching, or chemical mechanical polishing.

15. The bonding method according to claim 12, wherein
the temporarily bonding the first wafer stacking structure and a carrier wafer together, comprises:
bonding the first surface of the first wafer stacking structure that serves as a bonding surface and the carrier wafer together, wherein the first surface is a surface located at an outermost side of the first wafer stacking structure and is perpendicular to the stacking direction;
after the temporarily bonding the first wafer stacking structure and a carrier wafer together, the bonding method further comprises:
thinning a bottom wafer of the first wafer stacking structure until a through-silicon via (TSV) and a metal pillar in the TSV of the bottom wafer are exposed, wherein the bottom wafer is located at another outermost side of first wafer stacking structure, the another outermost side is perpendicular to the stacking direction, and the first surface is away from the bottom wafer.

16. The bonding method according to claim 1, wherein
the bonding a chip with good functions, which corresponds to a corresponding chip region with good functions determined in the operation of testing each chip region of the first wafer stacking structure, to a second wafer, comprises:
sequentially bonding a plurality of chips with good functions, which correspond to corresponding chip regions with good functions determined in the operation of testing each chip region of the first wafer stacking structure, to a second wafer through a chip-to-wafer bonding technology.

17. A wafer stacking structure, comprising:
a functional wafer; and
at least one first chip, bonded to the functional wafer, the first chip comprising at least two dies bonded together, and a test lead-out metal piece being formed on a die in an outer side of the first chip.

18. The wafer stacking structure according to claim 17, wherein
the first chip is obtained by dicing a first wafer stacking structure, and the first chip corresponds to a chip region that is determined to have good functions through testing in the first wafer stacking structure;
the die in the outer side of the first chip is bonded to the functional wafer or the other adjacent first chip.

19. A chip structure, comprising:
at least one first chip, the first chip comprising at least two dies bonded together, and a test lead-out metal piece being formed on a die in an outer side of the first chip.

20. The chip structure according to claim 19, wherein
the first chip is obtained by dicing a first wafer stacking structure, and the first chip corresponds to a chip region that is determined to have good functions through testing in the first wafer stacking structure;
the chip structure further comprises a functional die bonded to the die in the outer side of the first chip.
